(19) United States
(12) Patent Application Publication
(10) Pub. No.: US 2025/0239838 A1
(43) Pub. Date: Jul. 24, 2025

(54) Semiconductor Optical Amplifier for Data Distribution

(71) Applicant: SemiNex Corporation, Danvers, MA (US)

(72) Inventors: Sidi Aboujja, Middleton, MA (US); Daniel Yen Chu, Andover, MA (US); Ronald Moore, Boxford, MA (US)

(21) Appl. No.: 18/756,277

(22) Filed: Jun. 27, 2024

Related U.S. Application Data
(60) Provisional application No. 63/624,583, filed on Jan. 24, 2024.

(51) Int. Cl. H01S 5/50; G02B 6/125; H01S 5/02

(52) U.S. Cl. CPC H01S 5/50; G02B 6/125; H01S 5/021

(57) ABSTRACT

A silicon based photonic integrated circuit (Si-PIC) uses a semiconductor optical amplifier to overcome losses in the circuit from the input to the output ports.

### RELATED APPLICATIONS

This application claims the benefit under 35 USC 119(e) of U.S. Provisional Application No. 63/624,583, filed on Jan. 24, 2024, which is incorporated herein by reference in its entirety.

### BACKGROUND OF THE INVENTION

The demand for content on the internet has resulted in large data centers dedicated to the storage, download, upload, and cross communication of vast amounts of data. Each year the demand grows larger and larger. Today, the data centers communicate between the various servers by fiber optic cables, fiber optic amplifiers, fiber optic multiplexers, fiber optic splitters and fiber optic demultiplexers and electronic switches. FIG. 1 shows one example of a typical data center architecture (100). A data center provides access to either information stored or computing capabilities. The system provides centralized processing, storage, transmission, exchange, and management of information. These systems consist of many servers (101) that are interconnected by copper cables or fiber optic transmission systems with the information being routed by multiple and redundant switching networks. The sheer number of interconnections required in these data centers means that signals must be split hundreds, thousands, or tens of thousands of times to make up all the interconnections (101). Splitting the signals results in severe degradation of the signal power and can lead to high error rates if the signal levels are not returned to operational power levels. These signals often consist of tens, hundreds or more signals multiplexed together at different wavelengths that must be simultaneously amplified before, during and after splitting and routing. Today that amplification is accomplished with fiber optic amplifiers, introducing a bulky, expensive, and power intensive solution to the problem.

### SUMMARY OF THE INVENTION

In general, according to one aspect, the invention features a silicon based photonic integrated circuit (Si-PIC) that uses a semiconductor optical amplifier to overcome losses in the circuit from the input to the output ports.

In accordance with the present invention, photonic integrated circuits and systems as set forth in the independent claims, respectively, are provided. Preferred embodiments of the inventions are described in the dependent claims.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a schematic drawing showing an example of a hierarchical data center network.

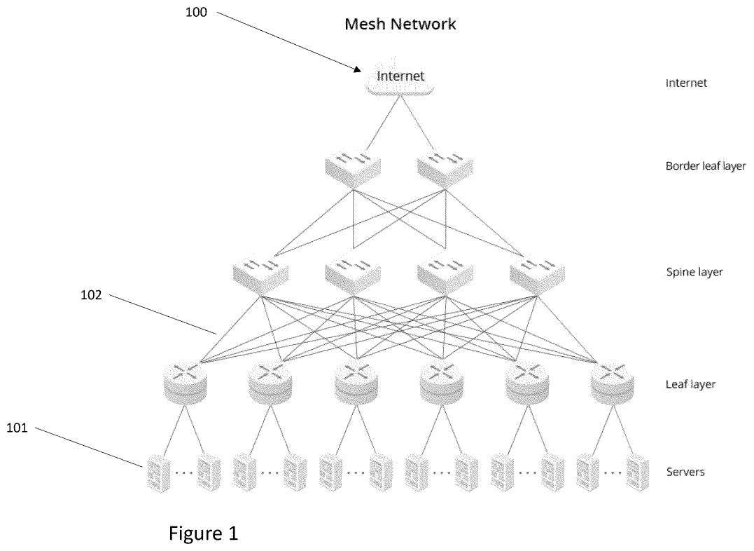

FIG. 2 is a schematic drawing showing a crossbar switch.

FIG. 3 is a schematic drawing showing a Semiconductor Optical Amplifier epi-structure.

FIG. 4 is a schematic drawing showing a Semiconductor Optical Amplifier band structure.

FIG. 5 is a schematic drawing showing a Semiconductor Optical Amplifier, mode field and transverse confinement.

FIG. 6 is a schematic drawing showing a Single junction semiconductor optical amplifier at 1550 nm providing up to 500 mW of gain as a power amplifier and 30 dB small signal gain as a pre-amplifier for a receiver.

FIG. 7 is a schematic drawing showing a multiple curve “s” type waveguide formed by real index guiding rib.

FIG. 8 is a schematic drawing showing a multiple curve “s” type waveguide formed by real index guiding rib.

FIG. 9 is a schematic drawing showing a 2×2 GaAs-PIC cross bar switch.

FIG. 10 is a schematic drawing showing a 2×2 Si-PIC cross bar switch with semiconductor optical amplifier inputs.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

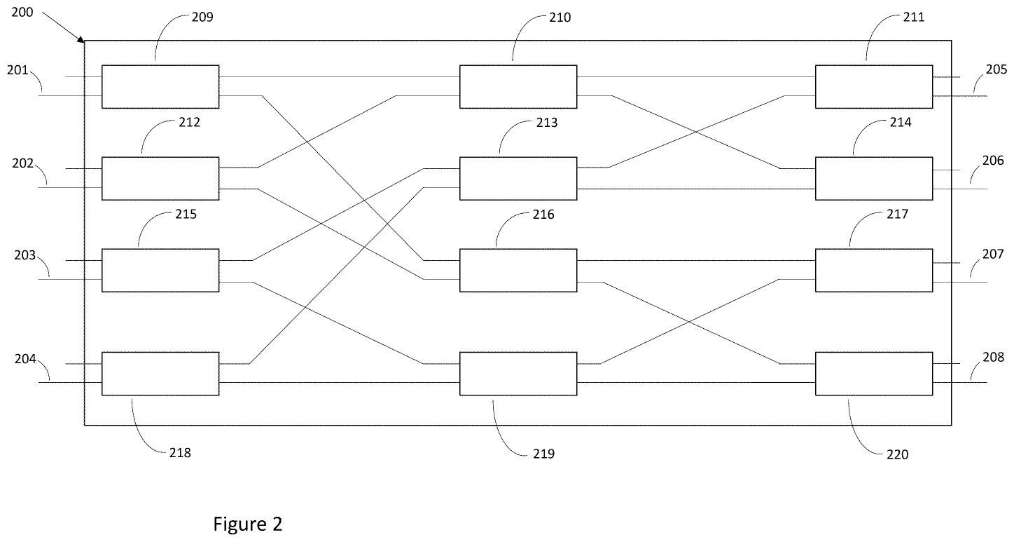

The next generation of data switches to be used in data centers will use photonic integrated circuits to create large crossbar switches. These switches will be arranged as shown in FIG. 2 where any input (201, 202, 203, 204) can be connected to any output (205, 206, 207, 208) through the switches (209-220). The issue with the photonic integrated circuits is the losses that will be incurred between the input and output which limits the number of switches that can be ganged together and consequently the number of input to output ports that can be connected on a given chip. A silicon based photonic integrated circuit cannot provide any gain in the optical path which means a semiconductor optical amplifier needs to be bonded or coupled into the system to provide the gain necessary to overcome the path losses. The path losses, depending on the size of the optical crossbar switch can exceed 10 dB to 20 dB or more. This invention can provide large signal gain of 17-25 dB boosting a 2 mW signal to 500 mW or more. This semiconductor optical amplifier design can also be used to create a photonic integrated circuit itself, such as the crossbar switch depicted in FIG. 2.

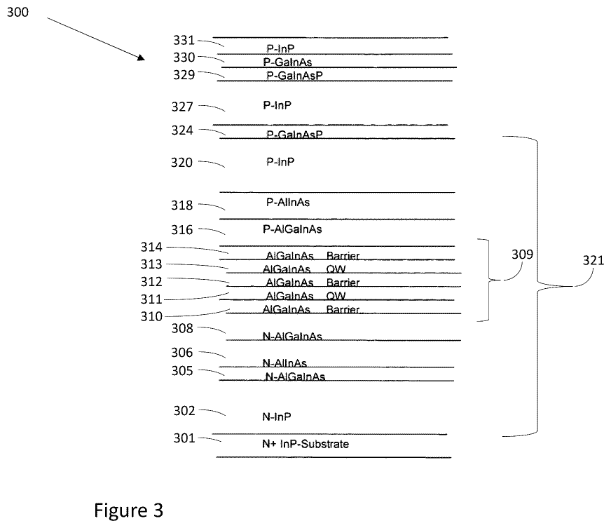

FIG. 3 shows the epi-structure for the device. The invention is a semiconductor optical amplifier using (AlGaInAs/GaInAsP/InP) material system and related combinations. Both the design of the active layer and the design of the optical cavity are optimized to minimize the temperature rise of the active region and to minimize the effects of elevated active layer temperature on the laser efficiency. The result is a high output power semiconductor optical amplifier for the wavelengths between 1.30 and 1.70 micrometers. The output power exceeds that exhibited by telecommunication lasers, which are required to have high modulation speeds at the expense of output power.

The active layer of the device is a strain compensated multi-quantum well structure (309) comprising an intraplanar compressively strained AlGaInAs wells (313, 311) and tensile strained AlGaInAs barrier layers (314, 310). The thickness of the quantum wells (313,311) are 7 nanometers (nm) or less. The strain is chosen to maximize the conduction band discontinuity while still staying below the critical thickness limit to preclude dislocation formation, so that at high operating temperatures electrons are not lost to the confinement layer due to thermal emission. The width of the wells (313,311) are adjusted to achieve the desired operating wavelength within the constraints of the critical layer thickness.

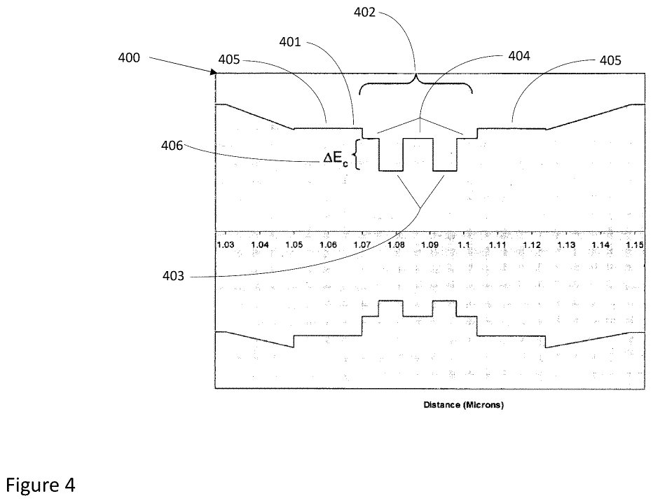

The active layer (309) is positioned within the center of an optical confinement layers (316-318,308-305) of either the step index type or the graded index type separate confinement heterostructure (GRINSCH). An InP layer (320,302) on each side forms the optical cladding layer for the optical confinement structure and the multi-quantum well (MQW) active layer (309). Lateral optical confinement is provided for by either a buried heterostructure or a ridge waveguide structure (FIG. 4).

The device is preferably of the vertical current injection type with the semiconductor layers of the SCH and cladding doped p-type, and the other set of the SCH and cladding doped n-type. Lateral current confinement is achieved by either buried Stripe geometry, or a ridge waveguide of raised ridge or dual trench formation. An alternative combination is implant, isolation, or mesa isolation, whereby oxide depositions confine the current to the central region of the lateral optical confinement structure.

Another aspect of the invention is the selection of the number of quantum wells in the active layer to minimize the thermal power dissipation density in the active layer, combined with a longer cavity length and cavity width to achieve Sufficient gain so that a high optical output power is obtained. Because the area of the junction is larger, the thermal resistance is reduced, thereby resulting in a lower junction temperature for the laser operation at a given output power.

FIG. 3 shows the layer structure of a semiconductor optical amplifier that has been constructed according to the principles of the present invention. Specifically, a listing of the epitaxial structure shown. It was fabricated or prepared using conventional III-V compound semiconductor epitaxial growth techniques such as metal organic chemical vapor deposition OMCVD (also referred to as MOCVD) and molecular beam epitaxy (MBE). The starting substrate (301) is n-type InP, onto which the sequence of layers is epitaxially grown using known methods.

Beginning from the substrate (301), a 1 micrometer thick n+InP lower cladding layer (302) with a silicon (Si) doping concentration of 3×10¹⁸ cm⁻³ is grown followed by a transition region 15 nm thick of lattice matched, graded (Al_{0.68}Ga_{0.32})_{0.47} In_{0.53}As to Al_{0.45}In_{0.52}.As (305-306) into the separate confinement heterostructure (SCH) layers (306-318). Next is the lower graded-index (GRIN) layer (308), which is 45 nm thick beginning with Al_{0.45}In_{0.52}As and ending with (Al_{0.59} Ga_{0.41})_{0.47}In_{0.53}As. The silicon doping concentration gradually decreases from the n-type lower cladding (302) through the transition layers (305-306) to the lower GRIN layer (308) where the silicon doping concentration reaches 5×10¹⁶ cm⁻³.

The undoped laser active layer (309) has a set of compressively strained AlGaInAs quantum wells (311 and 313), which are confined on each side by AlGaInAs barrier layers (310,312,314) under tensile strain such that the strains compensate each other and the critical thickness for dislocations is neutralized. Here, two quantum wells (311, 313) are shown each having a well thickness of 7 nm. The barrier layer thicknesses are 6 nm, 9 nm, and 5 nm for layers (310, 312, and 314), respectively.

Next the upper GRIN separate confinement layer (GRINSCH), which is 45 nm thick beginning with (AL_{0.59}Ga_{0.41})_{0.47}In_{0.53}As and ending with an interface layer of Al_{0.45}In_{0.52}As, which is grown on top of the laser active layer (319). Included in layer (318) is an additional layer of 5 nm of Al_{0.45}In_{0.52}As. The p-type Zn doping concentration gradually increased from 5×10¹⁶ cm⁻³ as growth proceeds toward the completion of layer 318, where the concentration reaches 1×10¹⁷ cm⁻³. Alternatively, a step index separate confinement heterostructure (SISCH) could be used in place of the GRINSCH as confinement about the active layer (309).

Above the GRIN layer (316-318) is grown the upper cladding layer (320) of 1.5 micrometer thick p-type InP Zn-doped at a concentration of 1×10¹⁷ cm⁻³. The layers (316, 318, and 320) mirror the lower layers of (306,305, and 302) in optical index profile and form the laser waveguide structure (321) about the active layer (309).

Low doping of p cladding good for optical transmission. This makes for lower crystal dislocations and optical scattering.

Above the upper cladding layer (320) are the p-ohmic contact layers (327-331). Between the cladding layer (320) and the contact layers (327-331), a 20 nm thick etch stop layer of p-Ga_{0.15}In_{0.85}As_{0.33}P_{0.67}, (324) is grown in order to provide a controlled stopping depth for etching the ridge waveguide during the laser processing. Next a 1 micrometer thick p-InP layer (327) Zn-doped at a concentration of 4×10¹⁷ cm⁻³ is grown followed by a p-type Ga_{0.29}In_{0.71}As_{0.62}P_{0.38} (329) Zn-doped at 2×10¹⁸ cm⁻³ graded to 1×10¹⁸ cm⁻³ Zn-doped Ga_{0.47}In_{0.53}As (330), which will be the ohmic contact formation layer during laser processing. Finally, a capping layer of p-InP (331) Zn doped at 1×10¹⁸ cm⁻³ is grown to complete the laser layer structure.

The detailed doping levels described are the preferred embodiment, but a range from 25% less to 50% more would be acceptable. The heavier doping densities above 1×10¹⁸ cm⁻³ can range higher by a factor of two to three as an acceptable range, as low electrical resistance is desired from these layers.

The layer thicknesses set forth above are the preferred embodiment, but a variation of 10% more or less is acceptable.

Consider now the quantum well dimensions and number for the preferred high-power application. Prior work has focused on lasers that required sufficient modulation bandwidth for telecommunications data transmission, which favored single mode short resonator cavity lengths such that the electrical impedance of the device is well matched for high-speed operation. For high optical output power, longer cavities are preferred as will be discussed below regarding heat dissipation. Secondly, good electron confinement to the quantum well with barriers that are significantly higher than the thermal Voltage or the expected non-thermal energy distribution of the electron energies within the junction active area is necessary.

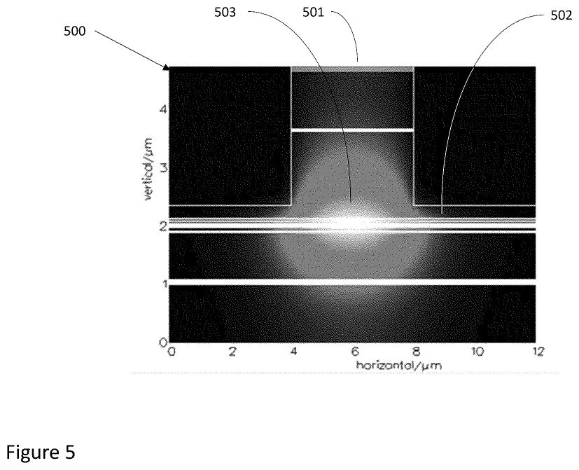

FIG. 5 shows the active layer band diagram schematically. Here, two quantum wells (403) are shown. In the strain compensated case of compressively strained AlGaInAs wells, the barrier layers (404) are under tensile strain, with the strain and thickness planned to Sum to Zero stress outside of the active layer well structure (402). The outside AlGaInAs layers (405) are lattice-matched to the InP lattice constant. Table 1 shows examples of the parameters and desired emission wavelength of the present invention.

TABLE 1

| Run | Structure | Material | Bandgap(nm) | Strain(%) | Width(nm) | ΔE [symbol] (eV) |
|---|---|---|---|---|---|---|
| A | Barrier | (Al_{0.3}Ga_{0.7})_{0.58}In_{0.42}As | 1094 | −0.8 | 9 | |
| | Quantum | (Al_{0.32}Ga_{0.68})_{0.29}In_{0.71}As | 1505 | 1.2 | 7 | 0.2 |
| | Well | | | | | |
| B | Barrier | (Al_{0.3}Ga_{0.7})_{0.58}In_{0.42}As | 1094 | −0.8 | 9 | |
| | Quantum | (Al_{0.46}Ga_{0.54})_{0.29}In [symbol] As | 1415 | 1.2 | 7 | 0.15 |
| | Well | | | | | |
| C | Barrier | (Al_{0.45}Ga_{0.55})_{0.58}In_{0.42}As | 980 | −0.8 | 9 | |
| | Quantiun | (Al_{0.54}Ga_{0.46})_{0.29}In_{0.71}As | 1354 | 1.2 | 7 | 0.15 |
| | Well | | | | | |

[symbol]

indicates data missing or illegible when filed

FIG. 5 shows the near field of the mode superimposed on the layer structure just described. The near field of the mode (503) is confined by the ridge (501) etched to the etch stop layer just above the upper fast axis guiding layer (502). The ridge can be 4 μm in width up to 6 mm in width depending on the power level the semiconductor optical amplifier is designed to support.

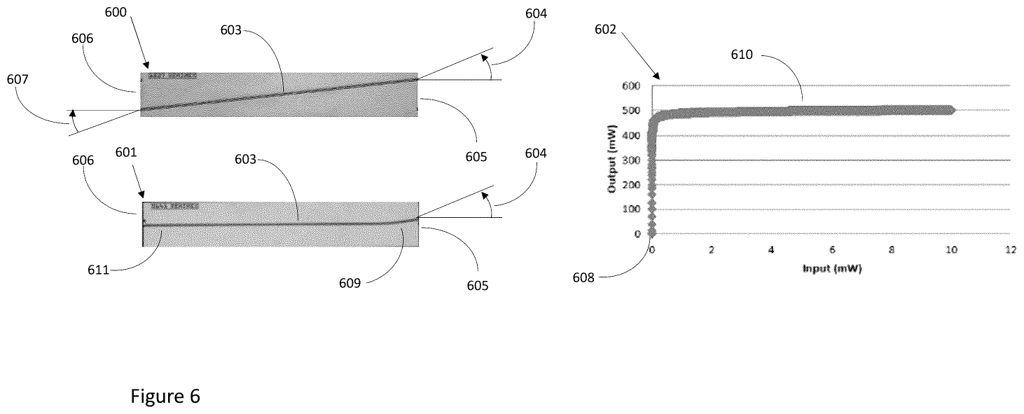

FIG. 6 shows the semiconductor optical amplifier ridge waveguide structures (603), from the p-contact side and the and power characteristics (602). The first embodiment (600) is a ridge waveguide (603) structure that is 4 μm, 5 μm or 6 μm in width to support a single mode in lateral direction as shown in FIG. 5. The input side of the waveguide is coated with low reflectivity coating (606) as is the output facet (605). The low reflectivity coating suppresses unwanted parasitic oscillations in the amplifier section, however at high gain levels, the amplifier may still be able to support unwanted modes oscillating. The ridge waveguide (603) is positioned at an angle of 4 degrees, 6 degrees or more from normal at both the input (607) and the output (604) facets. This angle adds additional suppression of unwanted modes and enables the 30 dB small signal gain exhibited by this amplifier design. A second version of the amplifier (601) is similar in design, but now a curve (609) is added to the ridge structure which enables the input waveguide (611) to be normal to the facet or tilted with respect to the normal to the facet while allowing the output waveguide to be tilted with respect to the normal at an angle of 4 degrees, 6 degrees or more. This design also provided the same 30 dB small signal gain and output power (610) as the first design using a straight ridge waveguide.

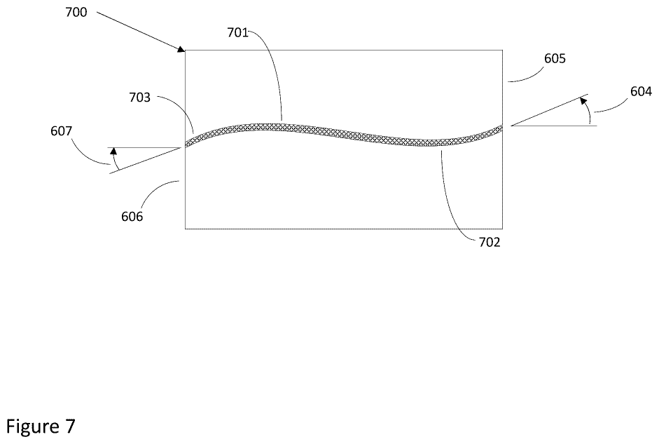

FIG. 7 is a third embodiment of the ridge waveguide structure (700) where multiple curves (701,702) can be used to provide mode filtering and suppression. This embodiment (700) is a ridge waveguide structure that is 4 μm, 5 μm or 6 μm in width (701,702) to support a single mode in lateral direction as shown in FIG. 5. The input side of the waveguide (606) is coated with low reflectivity coating (606) as is the output facet (605). The low reflectivity coating suppresses unwanted parasitic oscillations in the amplifier section, however at high gain levels, the amplifier may still be able to support unwanted modes oscillating. The input to the ridge waveguide (703) is positioned at an angle of 4 degrees, 6 degrees or more (607) from normal at either the input or the output facets. This angle adds additional suppression of unwanted modes and enables the 30 dB small signal gain exhibited by this semiconductor optical amplifier design. The bends in the ridge waveguide (701,702) provide additional mode filtering enabling wider ridge structures and additional filtering of unwanted parasitic modes.

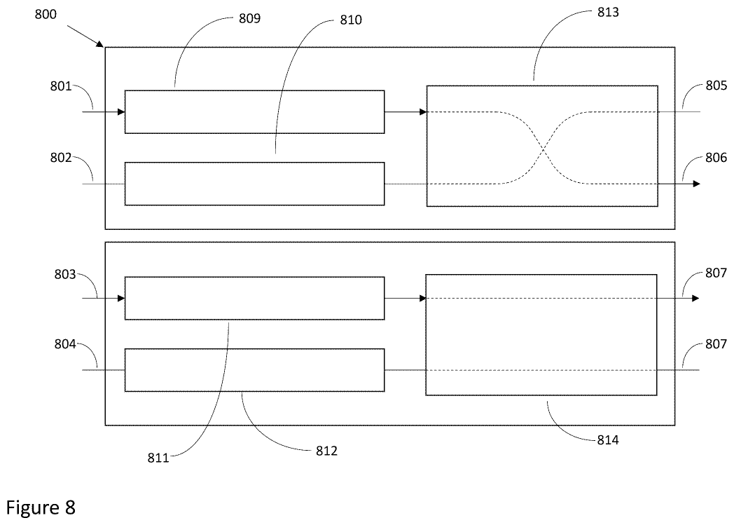

FIG. 8 shows a fourth embodiment of the invention, where the semiconductor optical amplifiers (809, 810, 811 and 812) are used to boost the input signal to the switching section which can be operated as a cross switch (813) or a bar switch (814). This is the fundamental building block of a data optical switch that can handle 2, 10, 100, or 1000 or more input and output ports. The semiconductor optical amplifiers (809, 810, 811 and 812) can be bonded to a silicon photonic integrated chip (Si-PIC) or be integral to a GaAs photonic integrated chip (GaAs-PIC). The semiconductor optical amplifiers can be at the input to the switch chip (813, 814) or embedded in a much larger network of switches. The switches on a Si-PIC can be a Mach-Zehnder type switch, or a biased multi-Mode Splitter type switch. The switches on a GaAs-PIC can be a Mach-Zehnder type switch, a biased multi-mode splitter switch or an electro-absorption switch.

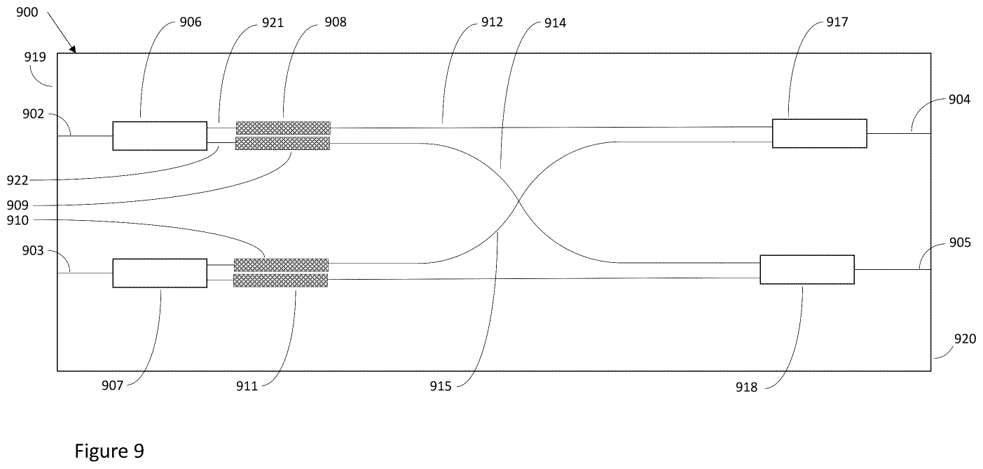

FIG. 9 shows a fifth embodiment of the invention which is the waveguide layout for 2×2 cross bar switch using GaAs. The signal at input power (902) can be a 4 μm, 5 μm or 6 μm ridge waveguide structure with a low reflectivity coating on the input facet (919). The input may also be tilted with regards to the normal to the facet at 4 degrees, 6 degrees or more as described in FIGS. 6 and 7. The input mode is the same as the mode described in FIG. 5 (503). The mode is split into two by the mode splitter (906). This mode splitter may be a simple bifurcated ridge, or it may be a multi-mode splitter. The multi-mode splitter works by allowing the single mode to stimulate the first order multimode in the wider waveguide structure. Depending on the bias on this section, i.e. transparent, the apparent length of the device will dictate the splitting of the mode. This apparent length can change by changing the bias point which changes the carrier concentration in this region and consequently the index of the region. This technique is suitable for making a variable splitting ratio device as well as a 1:2 splitter. The mode exiting the upper port (921) propagates next to the switch (908). Similarly, the mode exiting the lower power port (922) propagates to the switch (909). These switches can be one of two types, an electro-absorption switch or a Mach-Zehnder switch. The electro-absorption switch operates by simply reverse biasing the waveguide turning it into an absorption modulator. To enable this, there needs to be a deep etch between the splitter section (906) and the modulator section (908). This deep etch needs to completely remove the p-cap layers to electrically isolate the modulator sections (908,909) from the splitter section (906) and the next waveguide sections (912, 914). A reverse bias of a few volts to 4 volts or more is all that is required to create a completely opaque waveguide section and consequently switch off communication from the splitter ports (921,922) and the following waveguide sections (912, 914). This combination of splitters and electro-absorption modulators enables the mode from input (902) to be redirected via waveguides (912) or (914) to either of the two output ports (904,905). The preferred embodiment for the waveguide combiners (917,918) is a “Y” branch splitter, but a multi-mode splitter will also work but with higher losses in the reverse direction. The modulator section can also be a Mach-Zehnder type modulator, where the signal (921) is split into two signals, and a forward bias is applied to one leg of the waveguides to shift the phase until the output signal is nulled in a combiner before going on to the output waveguide. These types of modulators are well known to someone familiar with the state of the art. This process works also on the second input port (903) which is split (907), directed through two switches (910 and 911) to select which output port to route the signal to, and then recombined in either the combiner (917 or 918). This chip is constructed according to the epi-layer design in FIG. 3. The waveguide sections (914, 915) can be biased as semiconductor optical amplifiers according to the design shown in FIG. 6 to create sufficient gain to overcome any insertion losses or losses in the mode splitters and combiners. The crossover of waveguides (914 and 915) will have minimal effect on the signals in each of the branches because of the steep cross over angle, it is not possible for the modes to cross couple. There will be some noise introduced by the crossover since the two signals will affect the carrier density when the waveguide sections are biased to provide gain. However, the interaction length of the crossover is very small compared to the length of the amplifier sections (914,915). It should be noted that this is the building block for an n×m crossbar switch where the input and outputs can range from 2×2 to 1000×1000 or more.

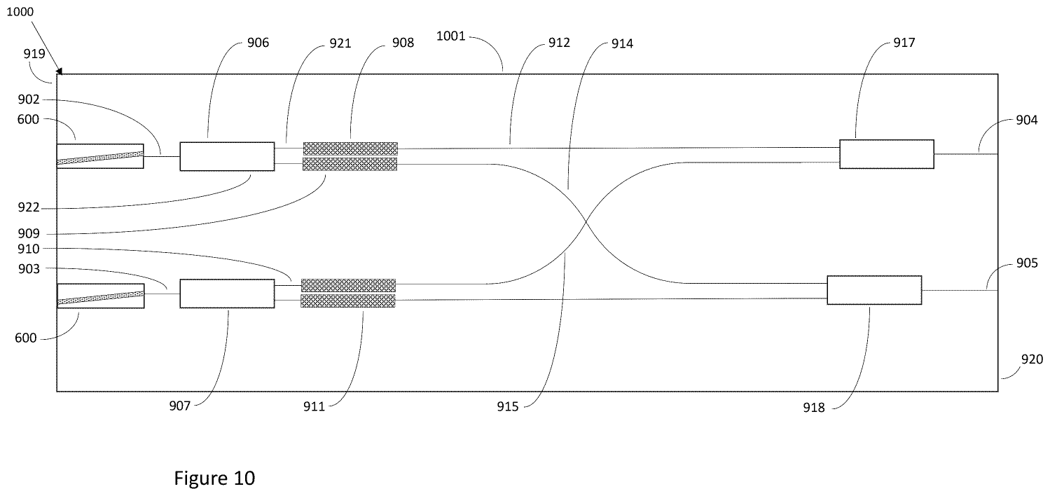

A sixth embodiment of the invention is shown in FIG. 10 where two semiconductor optical amplifiers (600) are used as the input to a Silicon photonic integrated circuit (Si-PIC) (1001). The semiconductor optical amplifiers (600) can be a 4 μm, 5 μm or 6 μm ridge waveguide structure with a low reflectivity coating on the input and output facets (606,605). The input and output may also be tilted (607, 604) with regards to the normal of the facet at an angle of 4 degrees, 6 degrees or more as described in FIGS. 6 and 7. The output mode is the same as the mode described in FIG. 5 (503). This mode is then injected into the silicon photonic integrated circuit (Si-PIC) (1001) by either direct coupling, a fiber optic, or a set of micro-optics. The mode is split into two by the mode splitter (906). This mode splitter may be a simple bifurcated ridge, or it may be a multi-mode splitter. The multi-mode splitter works by allowed in the single mode to stimulate the first order multimode in the wider waveguide structure. The length of the device will dictate the splitting of the mode as well as the losses of the splitter. The mode exiting the upper port (921) propagates next to the switch (908). Similarly, the mode exiting the lower power port (922) propagates to the switch (909). This is a Mach-Zehnder type switch. The Mach-Zehnder switch changes the phase of one leg of the interferometer by heating the waveguide which results in a low bandwidth. This combination of splitters and modulators enables the mode from input (902) to be redirected via waveguides (912) or (914) to either of the two output ports (904,905). Optical semiconductor amplifiers like the designs shown in FIGS. 6 and 7 can also be used at the output ports (904,905). The preferred embodiment for the waveguide combiners (917,918) is a “Y” branch splitter, but a multi-mode splitter will also work but with higher losses in the reverse direction. This process works also on the second input port (903) which is split (907), directed through two switches (910 and 911) to select which output port to route the signal to, and then recombined in either the combiner (917 or 918). The crossover of waveguides (914 and 915) will have minimal effect on the signals in each of the branches because of the steep cross over angle, it is not possible for the modes to cross couple. It should be noted that this is the building block for an n×m crossbar switch where the input and outputs can range from 2×2 to 1000×1000 or more.

While this invention has been particularly shown and described with references to preferred embodiments thereof, it will be understood by those skilled in the art that various changes in form and details may be made therein without departing from the scope of the invention encompassed by the appended claims.

### REFERENCES

1. https://community.fs.com/article/what-is-data-center-architecture.html
2. Ibrahimov, B. G., et al., “Research and Analysis of Fiber-Optic Communication Lines Based on Wave Multiplexing Technology,” Azerbaijan Technical University, 4-5 (2023).
3. D. Malka, Y. Danan, Y. Ramon and Z. Zalevsky, “A photonic 1×4 power splitter based on multi-mode interference in silicon gallium nitride slot waveguide structures,” Materials 2016, 9,516; doi:10.3390/ma9070516.

What is claimed is:

1. A silicon based photonic integrated circuit (Si-PIC) that uses a semiconductor optical amplifier to overcome losses in the circuit from the input to the output ports.

2. The Si-PIC of claim 1 that operates between the wavelengths of 1300 nm to 1700 nm.

3. The Si-PIC of claim 1 that uses a semiconductor optical amplifier with low reflectivity coatings on each facet.

4. The Si-PIC of claim 1 that uses a semiconductor optical amplifier with the input and output waveguides tilt at an angle of 4 degree, 6 degrees or more from the normal to the input and output facets.

5. The Si-PIC of claim 1 that uses a semiconductor optical amplifier with a curved ridge waveguide and the output is tilted at an angle of 4 degree, 6 degrees or more from the normal to the input and output facets.

6. The Si-PIC of claim 1 that uses a semiconductor optical amplifier with a curved ridge waveguide with multiple curves and the input and output waveguides are tilted an at an angle of 4 degree, 6 degrees or more from the normal to the input and output facets.

7. The Si-PIC of claim 1 that uses a semiconductor optical amplifier at the input of the Si-PIC.

8. The Si-PIC of claim 1 that uses a semiconductor optical amplifier at the output of the Si-PIC.

9. The Si-PIC of claim 1 that uses a semiconductor optical amplifier at the input and the output of the Si-PIC.

10. The Si-PIC of claim 1 that has n inputs where n≥1 and uses n semiconductor optical amplifiers.

11. The Si-PIC of claim 1 that has m outputs where m≥1 and uses m semiconductor optical amplifiers.

12. The Si-PIC of claim 1 that has n inputs where n≥1 and uses n semiconductor optical amplifiers and has m output where m≥1 and uses m semiconductor optical amplifiers and m=1.

13. The Si-PIC of claim 1 that has n inputs where n≥1 and uses n semiconductor optical amplifiers and has m output where m≥1 and uses m semiconductor optical amplifiers and m=n and any input channel n can be routed to any output channel m.

14. The Si-PIC of claim 1 that has n inputs where n≥1 and uses n semiconductor optical amplifiers and has m output where m≥1 and uses m semiconductor optical amplifiers and m=n and any input channel n can be routed to all output channels m.

15. The Si-PIC of claim 1 that has n inputs where n≥1 and uses n semiconductor optical amplifiers and has m output where m≥1 and uses m semiconductor optical amplifiers and m=n and any input channel n can be routed to any output channel m and the connection is bi-directional.

16. The Si-PIC of claim 14 that uses a heated waveguide to turn on and off a Mach-Zehnder output.

17. The Si-PIC of claim 14 that uses a pn junction to turn on and off a Mach-Zehnder output.

18. The Si-PIC of claim 14 that uses a modulator at the input and output to enable bi-directional communication.

19. A GaAs based photonic integrated circuit (GaAs-PIC) that is an active semiconductor optical amplifier system.

20. The GaAs-PIC of claim 19 that operates between the wavelengths of 1300 nm to 1700 nm.

21. The GaAs-PIC of claim 19 that uses a semiconductor optical amplifier with low reflectivity coatings on each facet.

22. The GaAs-PIC of claim 19 that uses a semiconductor optical amplifier with the input and output waveguides tilt at an angle of 4 degree, 6 degrees or more from the normal to the input and output facets.

23. The GaAs-PIC of claim 19 that uses a semiconductor optical amplifier with a curved ridge waveguide and the output is tilted at an angle of 4 degree, 6 degrees or more from the normal to the input and output facets.

24. The GaAs-PIC of claim 19 that uses a semiconductor optical amplifier with a curved ridge waveguide with multiple curves and the input and output waveguides are tilted an at an angle of 4 degree, 6 degrees or more from the normal to the input and output facets.

25. The GaAs-PIC of claim 19 that uses a semiconductor optical amplifier at the input of the GaAs-PIC.

26. The GaAs-PIC of claim 19 that uses a semiconductor optical amplifier at the output of the GaAs-PIC.

27. The GaAs-PIC of claim 19 that uses a semiconductor optical amplifier at the input and the output of the GaAs-PIC.

28. The GaAs-PIC of claim 19 that has n inputs where n≥1 and uses n semiconductor optical amplifiers.

29. The GaAs-PIC of claim 19 that has m outputs where m≥1 and uses m semiconductor optical amplifiers.

30. The GaAs-PIC of claim 19 that has n inputs where n≥1 and uses n semiconductor optical amplifiers and has m output where m≥1 and uses m semiconductor optical amplifiers and m=1.

31. The GaAs-PIC of claim 19 that is the optical amplifier by biasing each section of the ridge waveguide at different bias levels to provide transparency.

32. The GaAs-PIC of claim 19 that is the semiconductor optical amplifier by biasing each section of the ridge waveguide at different bias levels to provide gain.

33. The GaAs-PIC of claim 19 that is based on the semiconductor optical amplifier epi-structure described herein.

34. The GaAs-PIC of claim 19 that uses a reverse bias electro-absorption modulator to switch input channels on and off.

35. The GaAs-PIC of claim 19 that has n inputs where n≥1 and uses n semiconductor optical amplifiers and has m output where m≥1 and uses m semiconductor optical amplifiers and m=n and any input channel n can be routed to all output channels m.

36. The GaAs-PIC of claim 19 that has n inputs where n≥1 and uses n semiconductor optical amplifiers and has m output where m≥1 and uses m semiconductor optical amplifiers and m=n and any input channel n can be routed to any output channel m and the connection is bi-directional.

37. The GaAs-PIC of claim 19 that uses a heated waveguide to turn on and off a Mach-Zehnder output.

38. The GaAs-PIC of claim 19 that uses a pn junction to turn on and off a Mach-Zehnder output.

39. The GaAs-PIC of claim 19 that uses a modulator at the input and output to enable bi-directional communication.
